(19) United States
(12) Patent Application Publication
(10) Pub. No.: US 2017/0283247 A1
(43) Pub. Date: Oct. 5, 2017

(54) SEMICONDUCTOR DEVICE INCLUDING A MEMS DIE

(71) Applicant: Infineon Technologies AG, Neubiberg (DE)

(72) Inventors: Thorsten Meyer, Regensburg (DE); Dominic Maier, Pleystein (DE); Johannes Lodermeyer, Kinding (DE); Bernd Stadler, Donaustauf (DE)

(73) Assignee: Infineon Technologies AG, Neubiberg (DE)

(21) Appl. No.: 15/090,010

(22) Filed: Apr. 4, 2016

(51) Int. Cl. B81B 7/00; B81C 1/00

(52) U.S. Cl. CPC B81B 7/0051; B81C 1/00325; B81B 2201/0257; B81B 2203/0127; B81B 2203/0315; B81B 2207/095; B81C 2203/0145

(57) ABSTRACT

A semiconductor device includes a microelectromechanical system (MEMS) die, a lid, and an integrated circuit die. The lid is over the MEMS die and defines a cavity between the lid and the MEMS die. The integrated circuit die is attached to an inner side of the lid. The integrated circuit die is electrically coupled to the MEMS die.

### BACKGROUND

Semiconductor devices including a microelectromechanical system (MEMS) may include a cavity, which serves to protect a vibrating surface or membrane of the MEMS. For mobile devices and other devices, smaller packages for semiconductor devices including a MEMS are desired.

For these and other reasons, there is a need for the present invention.

### SUMMARY

One example of a semiconductor device includes a microelectromechanical system (MEMS) die, a lid, and an integrated circuit die. The lid is over the MEMS die and defines a cavity between the lid and the MEMS die. The integrated circuit die is attached to an inner side of the lid. The integrated circuit die is electrically coupled to the MEMS die.

### BRIEF DESCRIPTION OF THE DRAWINGS

FIG. 1A illustrates a cross-sectional view of one example of a semiconductor device including a microelectromechanical system (MEMS) die.

FIG. 1B illustrates a cross-sectional view of another example of a semiconductor device including a MEMS die.

FIGS. 2A-2G illustrate one example of a method for fabricating the semiconductor devices of FIGS. 1A and 1B.

FIG. 3 illustrates a cross-sectional view of another example of a semiconductor device including a MEMS die.

FIG. 4 illustrates a cross-sectional view of another example of a semiconductor device including a MEMS die.

FIG. 5 illustrates a cross-sectional view of another example of a semiconductor device including a MEMS die.

FIG. 6 illustrates a cross-sectional view of another example of a semiconductor device including a MEMS die.

### DETAILED DESCRIPTION

In the following Detailed Description, reference is made to the accompanying drawings, which form a part hereof, and in which is shown by way of illustration specific examples in which the disclosure may be practiced. In this regard, directional terminology, such as “top,” “bottom,” “front,” “back,” “leading,” “trailing,” etc., is used with reference to the orientation of the Figure(s) being described. Because components of examples can be positioned in a number of different orientations, the directional terminology is used for purposes of illustration and is in no way limiting. It is to be understood that other examples may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various examples described herein may be combined with each other, unless specifically noted otherwise.

As used herein, the term “electrically coupled” is not meant to mean that the elements must be directly coupled together and intervening elements may be provided between the “electrically coupled” elements.

Semiconductor devices including a microelectromechanical system (MEMS) die may include an application specific integrated circuit (ASIC) die where the MEMS die and the ASIC die are attached side by side to a printed circuit board (PCB). The MEMS die may be electrically coupled to the ASIC die via wire bonds. A metal lid may be attached over the MEMS die and the ASIC die. The metal lid may include an opening for receiving sound when the MEMS die includes a microphone. To achieve a higher integration in the package and thus a more compact package, examples of the semiconductor devices described herein include arranging an integrated circuit die (e.g., an ASIC die) in or on a lid capping a MEMS die. In this way, the lateral dimensions of the packages are greatly reduced.

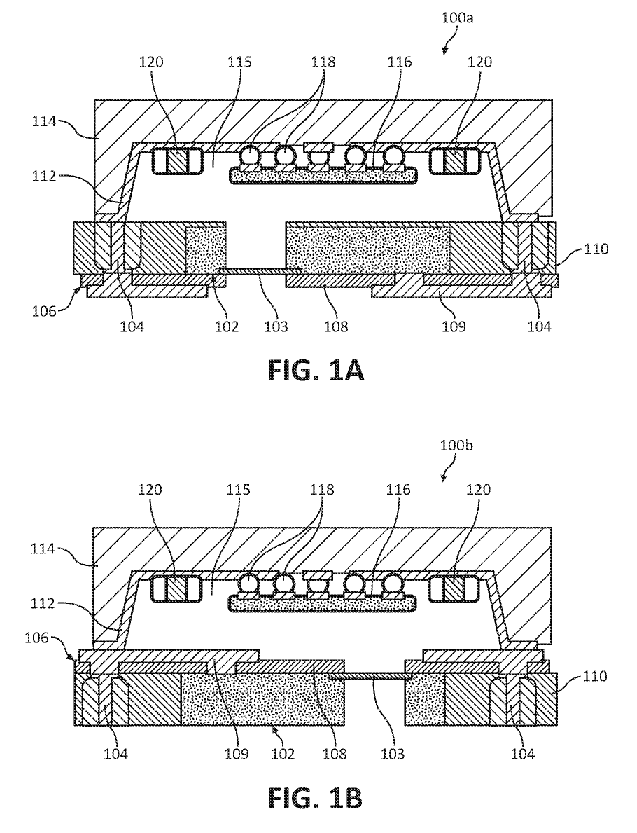

FIG. 1A illustrates a cross-sectional view of one example of a semiconductor device 100a. Semiconductor device 100a includes a MEMS die 102, via elements 104, a redistribution layer 106, encapsulation material 110, a metallization layer 112, a lid 114, an integrated circuit die 116, contact elements 118, and passive components 120. MEMS die 102 includes a membrane 103 facing away from lid 114. In one example, MEMS die 102 includes a microphone and membrane 103 is used to sense a sound signal. Integrated circuit die 116 may be an ASIC die to process the signal sensed by MEMS die 102.

Encapsulation material 110 laterally surrounds MEMS die 102 and via elements 104. Encapsulation material 110 may include a mold compound, a polymer, or another suitable dielectric material. Redistribution layer 106 is formed on the bottom surface of encapsulation material 110, MEMS die 102, and via elements 104. Redistribution layer 106 electrically couples MEMS die 102 to via elements 104. Redistribution layer 106 includes a dielectric material 108 and a conductive material 109 providing signal traces and contact elements for electrically coupling semiconductor device 100a to a circuit board, such as a PCB.

Via elements 104 extend through encapsulation material 110 to electrically couple redistribution layer 106 to metallization layer 112. In one example, via elements 104 may be prefabricated (e.g., via bars or embedded z-lines (EZLs)) and encapsulated in encapsulation material 110 with MEMS die 102. In another example, via elements 104 may be formed after encapsulating MEMS die 102, such as by drilling a through-hole through encapsulation material 110 and filling the through-hole with a conductive material. In yet other examples, via elements 104 may include other suitable electrically conductive elements to electrically couple redistribution layer 106 to metallization layer 112.

Lid 114 defines a cavity 115 over MEMS die 102 and encapsulation material 110. Cavity 115 may provide a back volume for MEMS die 102. Lid 114 may include a non-conductive material, such as a mold compound, a polymer, or another suitable dielectric material. In one example, lid 114 includes the same material as encapsulation material 110. In other examples, lid 114 includes a different material from encapsulation material 110. Lid 114 may be thinned after attachment over MEMS die 102 by grinding or another suitable process to reduce the vertical dimensions of semiconductor device 100a.

Metallization layer 112 is attached to the inner surface and bottom surface of lid 114. Portions of metallization layer 112 attached to the bottom surface of lid 114 are electrically coupled to via elements 104 using solder or another suitable electrically conductive material. Metallization layer 112 may be applied onto the inner surface and the bottom surface of lid 114 using a deposition process (e.g., physical vapor deposition), a plating process (e.g., electroless plating), a printing process, or another suitable process. Metallization layer 112 may be structured after being applied to the inner surface and the bottom surface of lid 114 using a lithography and etching process or another suitable process.

Integrated circuit die 116 (e.g., an ASIC die) is attached to the inner side of lid 114. Integrated circuit die 116 may include a flip chip package, an embedded wafer level ball grid array (eWLB) package, or another suitable package. Integrated circuit die 116 is electrically coupled to metallization layer 112 via contact elements 118 (e.g., solder balls). Passive components 120, such as surface mount device (SMD) components, land side capacitors (LSCs), and/or integrated passive devices (IPDs), are electrically coupled to metallization layer 112 via solder or another suitable electrically conductive material. Metallization layer 112 electrically couples integrated circuit die 116 and passive components 120 to each other and to via elements 104 such that integrated circuit die 116 is electrically coupled to MEMS die 102. Metallization layer 112 may also provide electromagnetic shielding for MEMS die 102 and/or integrated circuit die 116.

Semiconductor device 100a provides a number of advantages over previous devices. Semiconductor device 100a includes reduced lateral dimensions due to the integration of integrated circuit die 116 and passive components 120 on lid 114. Semiconductor device 100a also includes reduced vertical dimensions since lid 114 may be thinned after attachment over MEMS die 102.

FIG. 1B illustrates a cross-sectional view of another example of a semiconductor device 100b. Semiconductor device 100b is similar to semiconductor device 100a previously described and illustrated with reference to FIG. 1A, except that semiconductor device 100b includes redistribution layer 106 facing lid 114. In this example, metallization layer 112 is electrically coupled to via elements 104 through redistribution layer 106. Via elements 104 may electrically couple semiconductor device 100b to a circuit board, such as a PCB. In this example, membrane 103 of MEMs die 102 faces lid 114, which may provide better mechanical protection for membrane 103 compared to semiconductor device 100a where membrane 103 faces away from lid 114.

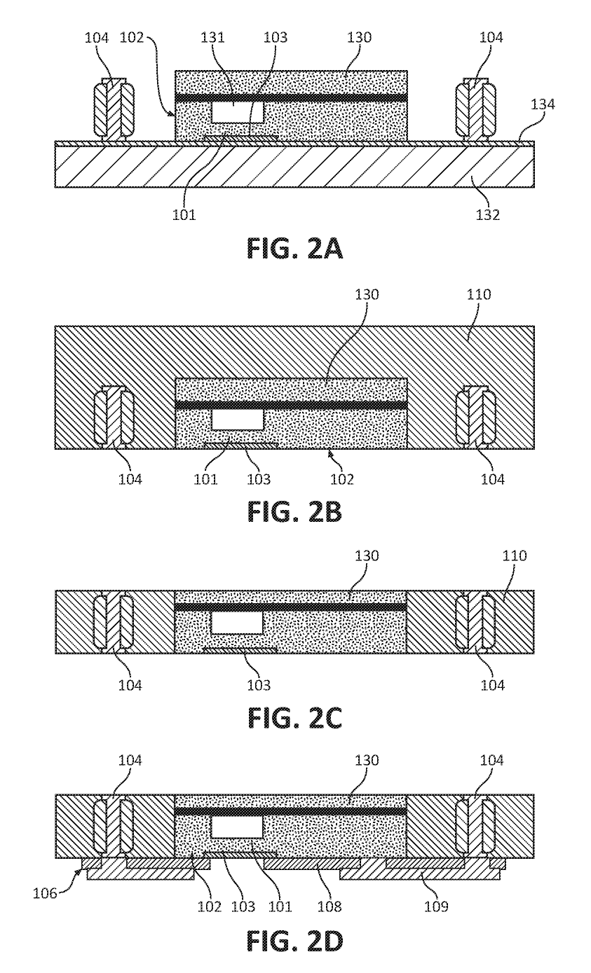

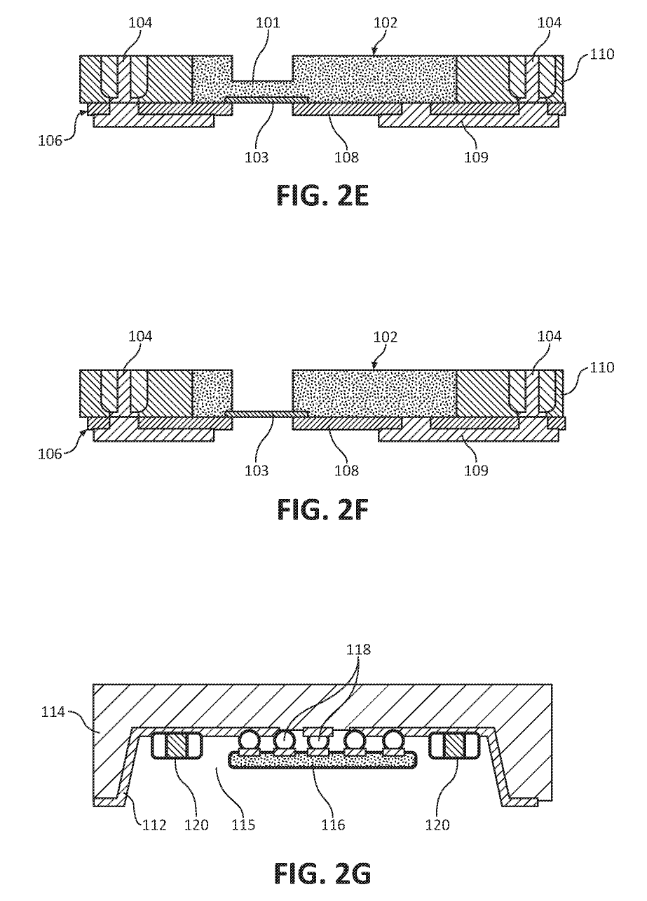

FIGS. 2A-2G illustrate one example of a method for fabricating semiconductor devices 100a and 100b of FIGS. 1A and 1B, respectively. FIG. 2A illustrates a cross-sectional view of one example of a semiconductor device after a first stage of the fabrication process. A carrier 132 with a carrier tape 134 applied to the upper surface of the carrier is provided. A MEMS die 102 with a cap 130 is placed on carrier tape 134. MEMS die 102 includes excess semiconductor material 101 to protect membrane 103 during the beginning stages of the fabrication process. Cap 130 protects MEMS die 102 and a cavity 131 between cap 130 and excess semiconductor material 101 during the beginning stages of the fabrication process. Via elements 104 are placed on carrier tape 134 adjacent to MEMS die 102.

FIG. 2B illustrates a cross-sectional view of one example of a semiconductor device after a second stage of the fabrication process. MEMS die 102, cap 130, and via elements 104 are encapsulated with an encapsulation material 110 (e.g., a mold material, a polymer). MEMS die 102, cap 130, and via elements 104 may be encapsulated using an injection molding process, a dispensing process, a printing process, or another suitable process. After encapsulation, carrier 132 and carrier tape 134 are removed from the bottom surfaces of MEMS die 102, via elements 104, and encapsulation material 110.

FIG. 2C illustrates a cross-sectional view of one example of the semiconductor device after a third stage of the fabrication process. A portion of the top side of encapsulation material 110 and a portion of the top side of cap 130 are removed using a grinding process or another suitable process to expose an upper surface of via elements 104.

FIG. 2D illustrates a cross-sectional view of one example of the semiconductor device after a fourth stage of the fabrication process. A redistribution layer 106 is formed on the bottom surfaces of MEMS die 102, via elements 104, and encapsulation material 110. Deposition, lithography, and etching processes may be used to fabricate redistribution layer 106. Redistribution layer 106 includes a dielectric material 108 and a conductive material 109 providing signal traces and contacts to electrically couple MEMS die 102 to via elements 104 and for electrically coupling the semiconductor device to a circuit board. The exposed portions of conductive material 109 may be plated with a noble metal (e.g., gold).

FIG. 2E illustrates a cross-sectional view of one example of a semiconductor device after a fifth stage of the fabrication process. A portion of the top side of encapsulation material 110, a portion of the top side of each via element 104, and the remaining portion of cap 130 are removed using a grinding process or another suitable process to expose MEMS die 102 including excess semiconductor material 101 over membrane 103.

FIG. 2F illustrates a cross-sectional view of one example of a semiconductor device after a sixth stage of the fabrication process. Excess semiconductor material 101 is removed using an etching process to expose the upper surface of membrane 103.

FIG. 2G illustrates a cross-sectional view of one example of a lid assembly for the semiconductor device. The lid assembly includes a metallization layer 112, a lid 114, an integrated circuit die 116, contact elements 118, and passive components 120. Lid 114 may include a non-conductive material (e.g., a mold material, a polymer) and defines a cavity 115. Lid 114 may be fabricated using an injection molding process, a milling process, a 3D printing process, or another suitable process. Metallization layer 112 includes signal traces to electrically interconnect integrated circuit die 116, passive components 120, and MEMS die 102 (FIG. 2F). Metallization layer 112 is formed on the inner surface and bottom surface of lid 114 using deposition, lithography, and etching processes, a printing process, a plating process (e.g., electroless plating), or other suitable processes.

Integrated circuit die 116 is then electrically coupled to metallization layer 112 via contact elements 118. Integrated circuit die 116 may include a flip chip package, an eWLB package, or another suitable package. Passive components 120 may be electrically coupled to metallization layer 112 via solder or another suitable electrically conductive material. Passive components 120 may include SMD components, LSCs, and/or IPSs. In this example, passive components 120 are electrically coupled to the surface of metallization layer 112 facing away from lid 114. In other examples, however, passive components 120 may be embedded within lid 114 and electrically coupled to the surface of metallization layer 112 facing lid 114.

In one example, the lid assembly is then attached over MEMS die 102 of FIG. 2F with redistribution layer 106 facing away from the lid assembly. Metallization layer 112 is electrically coupled to via elements 104 via solder or another suitable electrically conductive material to provide semiconductor device 100a previously described and illustrated with reference to FIG. 1A. In another example, the lid assembly is attached over MEMS die 102 of FIG. 2F with redistribution layer 106 facing the lid assembly. Metallization layer 112 is electrically coupled to redistribution layer 106 via solder or another suitable electrically conductive material to provide semiconductor device 100b previously described and illustrated with reference to FIG. 1B. In either example, after attaching the lid assembly over MEMS die 102, lid 114 may be thinned by grinding or another suitable process to reduce the vertical dimensions of the semiconductor device.

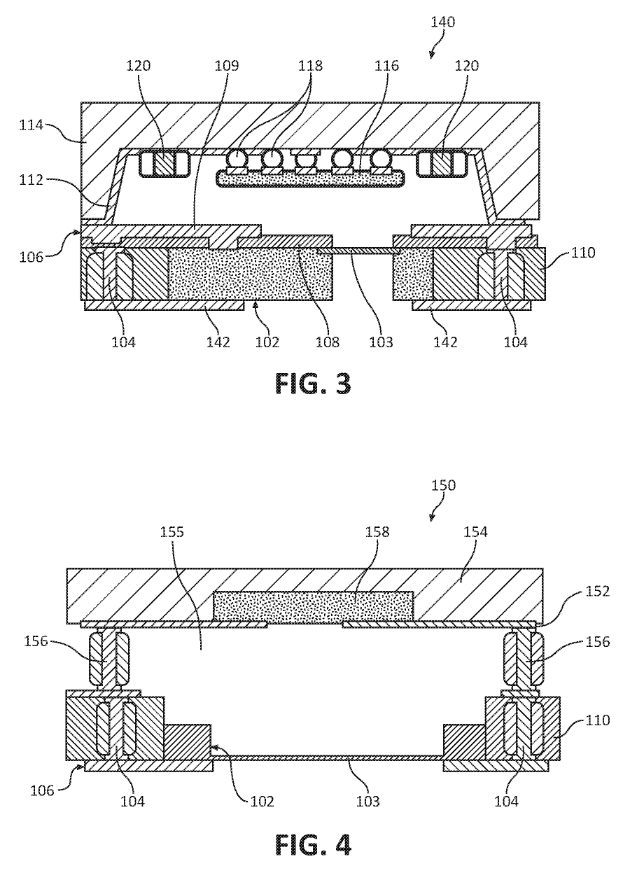

FIG. 3 illustrates a cross-sectional view of another example of a semiconductor device 140. Semiconductor device 140 is similar to semiconductor device 100b previously described and illustrated with reference to FIG. 1B, except that semiconductor device 140 includes a conductive layer 142. Conductive layer 142 is electrically coupled to via elements 104 and may include signal traces and/or contacts to electrically couple semiconductor device 140 to a circuit board. Conductive layer 142 may include a noble metal or another suitable conductive material. Conductive layer 142 may be formed using a deposition process (e.g., physical vapor deposition), a plating process (e.g., electroless plating), a printing process, or another suitable process.

FIG. 4 illustrates a cross-sectional view of another example of a semiconductor device 150. Semiconductor device 150 includes a MEMS die 102, via elements 104, a redistribution layer 106, encapsulation material 110, a metallization layer 152, a lid 154, contact elements 156, and an integrated circuit die 158. In this example, lid 154 is planar and integrated circuit die 158 is embedded within the lower side of lid 154. Metallization layer 152 is attached to the lower side of lid 154 and integrated circuit die 158 and electrically couples integrated circuit die 158 to contact elements 156. Contact elements 156 are electrically coupled to metallization layer 152 via solder or another suitable electrically conductive material. In one example, metallization layer 152, lid 154, and integrated circuit die 158 are part of an eWLB package that provides the lid assembly for semiconductor device 150.

Contact elements 156 electrically couple metallization layer 152 to via elements 104 and define the height of cavity 155 over MEMS die 102. Contact elements 156 may be similar to via elements 104 or different from via elements 104. Contact elements 156 may be prefabricated (e.g., via bars or EZLs) or other suitable contact elements. Each contact element 156 is stacked on a via element 104 and electrically coupled to the via element 104 using solder or another suitable electrically conductive material. In other examples, more than one contact element 156 may be stacked on each via element 104 to define the height of cavity 155 over MEMS die 102 and/or the height of semiconductor device 150.

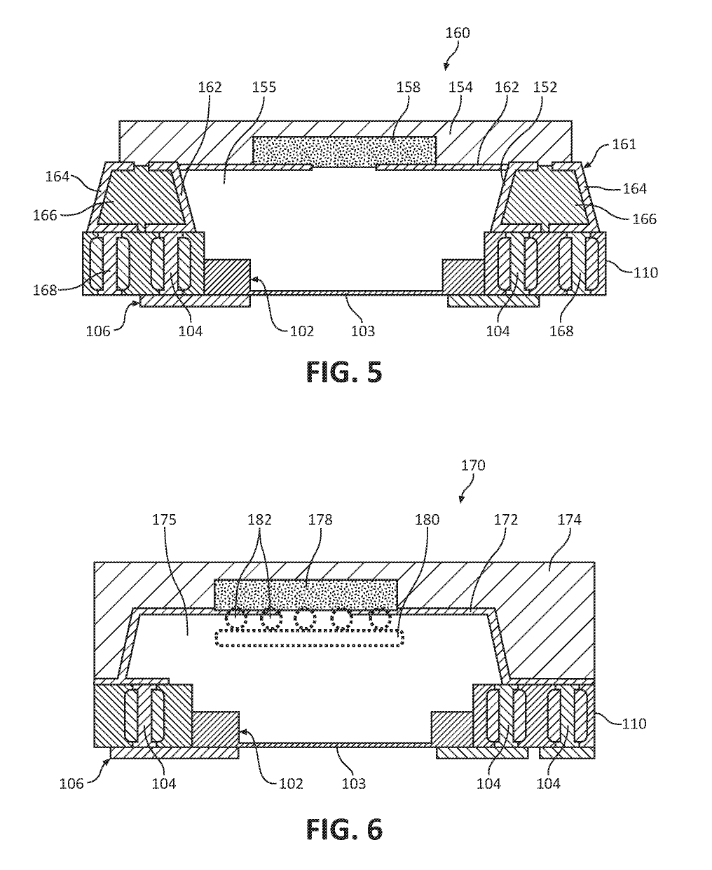

FIG. 5 illustrates a cross-sectional view of another example of a semiconductor device 160. Semiconductor device 160 includes a MEMS die 102, via elements 104, a redistribution layer 106, encapsulation material 110, a metallization layer 152, a lid 154, an integrated circuit die 158, a contact element 161, and via elements 168. Contact element 161 may be ring shaped and includes a first metallization layer 162, a second metallization layer 164, and a spacer 166.

Via elements 168 extend through encapsulation material 110 between via elements 104 and the sidewalls of semiconductor device 160. In one example, via elements 168 may be prefabricated (e.g., via bars or EZLs) and encapsulated in encapsulation material 110 with MEMS die 102 and via elements 104. In another example, via elements 168 may be formed after encapsulating MEMS die 102, such as by drilling a through-hole through encapsulation material 110 and filling the through-hole with a conductive material. In yet other examples, via elements 168 may include other suitable electrically conductive elements.

Spacer 166 may include an encapsulation material (e.g., a mold material, a polymer) or another suitable dielectric material onto which metallization layers 162 and 164 are formed. Spacer 166 defines the height of cavity 155 over MEMS die 102 and/or the height of semiconductor device 160. Spacer 166 may be fabricated using an injection molding process, a milling process, a 3D printing process, or another suitable process. In the example illustrated in FIG. 5, spacer 166 has a trapezoidal shape in cross-section. In other examples, however, spacer 166 may have another suitable shape in cross-section, such as a rectangular shape.

First metallization layer 162 of contact element 161 extends across a portion of the upper surface of spacer 166, an inner side surface of spacer 166, and a portion of the lower surface of spacer 166. Second metallization layer 164 of contact element 161 extends across a portion of the upper surface of spacer 166, an outer side surface of spacer 166, and a portion of the lower surface of spacer 166. First metallization layer 162 is electrically coupled to metallization layer 152 and via elements 104 via solder or another suitable electrically conductive material. Second metallization layer 164 is electrically coupled to via elements 168 via solder or another suitable electrically conductive material. Second metallization layer 164 and via elements 168 hermetically seal semiconductor device 160. In one example, metallization layers 162 and 164 have the same thickness. In other examples, metallization layers 162 and 164 have different thicknesses. Metallization layers 162 and 164 may be formed using a deposition process (e.g., physical vapor deposition), a plating process (e.g., electroless plating), a printing process, or another suitable process.

FIG. 6 illustrates a cross-sectional view of another example of a semiconductor device 170. Semiconductor device 170 includes a MEMS die 102, via elements 104, a redistribution layer 106, encapsulation material 110, a metallization layer 172, a lid 174, an integrated circuit die 178 and/or an integrated circuit die 180. In this example, lid 174 defines a cavity 175 between lid 174 and MEMS die 102. In one example, an integrated circuit die 178 is embedded within the inner side of lid 174. In another example, in place of integrated circuit die 178 or in addition to integrated circuit die 178, an integrated circuit die 180 is attached to the inner side of lid 174 via contact elements 182.

Metallization layer 172 is attached to the inner surface and the bottom surface of lid 174 and electrically couples integrated circuit die 178 and/or integrated circuit die 180 to via elements 104. As illustrated in FIG. 6, semiconductor device 170 may include two rows of via elements 104 on at least one side of MEMS die 102. In other examples, more than two rows of via elements 104 may be on at least one side of MEMS die 102. By having two rows of via elements 104 on at least one side of MEMS die 102, a higher number of connections may be made to semiconductor device 170 or a higher pitch may be provided between via elements 104.

Each semiconductor device 100a, 100b, 140, 150, 160, and 170 previously described and illustrated with reference to FIGS. 1A, 1B, and 3-6, respectively, may also include a coating on the outer top and outer side surfaces to hermetically seal the semiconductor devices. In one example, the coating may include a parylene coating applied from a vapor phase at a low temperature (e.g., 150° C.) to a suitable thickness (e.g., 1 μm or greater).

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A semiconductor device comprising:
a microelectromechanical system (MEMS) die;
a lid that includes an inner surface and a bottom surface, wherein the inner surface of the lid is over the MEMS die and defines a cavity between the inner surfaced and the MEMS die, wherein a metallization layer is attached to the inner surface and the bottom surface of the lid; and
an integrated circuit die attached to the metallization layer at the inner surface of the lid, the integrated circuit die electrically coupled to the MEMS die through the metallization layer at the inner surface and the bottom surface of the lid.

2. The semiconductor device of claim 1, further comprising:
a passive component attached to the metallization layer at the inner surface of the lid, wherein the metallization layer at the inner surface of the lid electrically couples the passive component to the integrated circuit die.

3. The semiconductor device of claim 1, further comprising:
an encapsulation material laterally surrounding the MEMS die;
a redistribution layer on the encapsulation material and the MEMS die, wherein the redistribution layer includes a conductive material that is attached to the MEMS die; and
a via element extending through the encapsulation material,
wherein the integrated circuit die is electrically coupled to the MEMS die through the conductive material, the via element and the metallization layer at the bottom surface and the inner surface of the lid.

4. (canceled)

5. The semiconductor device of claim 1, wherein the MEMS die comprises a microphone.

6. The semiconductor device of claim 1, wherein the integrated circuit die is embedded within the inner surface of the lid.

7. A semiconductor device comprising:
a microelectromechanical system (MEMS) die;
an encapsulation material laterally surrounding the MEMS die;
a via element extending through the encapsulation material;
a redistribution layer electrically coupling the MEMS die to the via element; and
a lid assembly comprising a lid having an inner surface and a bottom surface, a metallization layer that is attached to the inner surface and the bottom surface of the lid, and an application specific integrated circuit (ASIC) die that is attached to the metallization layer at the inner surface of the lid, wherein the inner surface of the lid is over the ASIC die, and wherein the ASIC die is electrically coupled to the MEMS die through the metallization layer at the inner surface and the bottom surface of the lid, the via element and the redistribution layer.

8. The semiconductor device of claim 7, wherein the MEMS die comprises a membrane, and wherein the metallization layer at the bottom surface of the lid is electrically coupled to the redistribution layer through the via element such that the membrane faces away from the lid.

9. The semiconductor device of claim 7, wherein the MEMS die comprises a membrane, and wherein the metallization layer at the bottom surface of the lid is electrically coupled to the via element through the redistribution layer such that the membrane faces the lid.

10. The semiconductor device of claim 7, wherein the semiconductor device is hermetically sealed.

11. The semiconductor device of claim 10, wherein the semiconductor device is hermetically sealed via a parylene coating.

12. The semiconductor device of claim 7, wherein the ASIC die is embedded in the lid.

13. The semiconductor device of claim 7, further comprising:
a contact element between the lid assembly and the via element, the contact element electrically coupling the metallization layer at the bottom surface of the lid to the via element.

14. The semiconductor device of claim 7, wherein the lid is planar.

15. The semiconductor device of claim 7, wherein the inner surface of the lid defines a cavity over the MEMS die.

16. A method for fabricating a semiconductor device, the method comprising:
encapsulating a microelectromechanical system (MEMS) die and via elements with an encapsulation material;
removing a portion of the encapsulation material to expose the MEMS die and the via elements;
forming a redistribution layer to electrically couple the MEMS die to the via elements; and
attaching a lid assembly over the MEMS die, wherein the lid assembly comprises a lid having an inner surface and a bottom surface, a metallization layer that is attached to the inner surface and the bottom surface of the lid, and an integrated circuit die that is attached to the metallization layer at the inner surface of the lid, wherein the lid assembly is attached over the MEMS die such that the inner surface of the lid is over the MEMS die and the metallization layer at the inner surface and the bottom surface of the lid electrically couples the integrated circuit die to the MEMS die through the via elements and the redistribution layer.

17. The method of claim 16, further comprising:
placing the MEMS die and the via elements on a carrier prior to encapsulating; and
removing the carrier after encapsulating.

18. The method of claim 16, wherein attaching the lid assembly comprises attaching the lid assembly such that the metallization layer at the bottom surface of the lid is electrically coupled to the via elements through the redistribution layer and the redistribution layer faces the lid assembly.

19. The method of claim 16, wherein attaching the lid assembly comprises attaching the lid assembly such that the metallization layer at the bottom surface of the lid is electrically coupled to the redistribution layer through the via elements and the redistribution layer faces away from the lid assembly.

20. The method of claim 16, further comprising:
thinning the lid after attaching the lid assembly.

21. A semiconductor device comprising:
a microelectromechanical system (MEMS) die;
a lid over the MEMS die defining a cavity between an inner surface of the lid and the MEMS die;
a passive component attached to the inner surface of the lid;
an integrated circuit die attached to the inner surface of the lid;
an encapsulation material laterally surrounding the MEMS die;
a redistribution layer on the encapsulation material and the MEMS die;
a via element extending through the encapsulation material;
and
a metallization layer attached to the inner surface and a bottom surface of the lid, wherein the metallization layer at the inner surface is electrically coupled to the integrated circuit die and the passive component, wherein the metallization layer at the inner surface and the bottom surface of the lid electrically couples the integrated circuit die to the MEMS die through the via element and the redistribution layer,
wherein the integrated circuit die is embedded within the inner side of the lid, and wherein the MEMS die comprises a microphone.

22-26. (canceled)
